(19) United States
(12) Patent Application Publication
(10) Pub. No.: US 2025/0306129 A1
(43) Pub. Date: Oct. 2, 2025

(54) SENSOR AND SENSOR MIS-WIRING DIAGNOSTIC

(71) Applicant: Rosemount Inc., Shakopee, MN (US)

(72) Inventors: Ryan Reed Carlson, Minnetonka, MN (US); Andrew James Bronczyk, Cologne, MN (US); Kevin Mitchell Grove, Richfield, MN (US); Samuel Victor Haarala, Chaska, MN (US)

(21) Appl. No.: 18/621,374

(22) Filed: Mar. 29, 2024

(51) Int. Cl. G01R 31/55; G01K 1/02; G01K 7/02

(52) U.S. Cl. CPC G01R 31/55; G01K 1/026; G01K 7/02

(57) ABSTRACT

A temperature transmitter assembly includes a sensor and measurement circuitry. The sensor includes a first conductor, a second conductor, and a third conductor configured to provide leads for two thermocouples. The first conductor and the third conductor are leads for the first thermocouple and have a first measurement point at a first location. The second conductor and the third conductor are leads for the second thermocouple and have a second measurement point at a second location a distance from the first location at a surface of a process conduit. The measurement circuitry includes three terminals, a first terminal for the first conductor, a second terminal for the second conductor, and a third terminal for the third conductor. The measurement circuitry is configured to determine an output related to a temperature at each thermocouple measurement point, the output indicative of a wiring state of the three conductors to the three terminals.

### BACKGROUND

Since thermocouples are polarized, mis-wiring of thermocouple sensor leads in a use setting can lead to incorrect determinations of temperature. Further, such mis-wirings may have outputs that are difficult to distinguish from misconfiguration, sensor installation issues, faulty sensors, or the like. Mis-wiring can occur at a transmitter terminal block, or at any extension wiring connection between a sensor and the transmitter terminal block.

Miswiring issues are further complicated since there are numerous types of two wire thermocouples, each with their own wire and insulation color standard, and since there are a number of different color standards depending on where the thermocouples are manufactured or being sold. For example only, United States color code (ANSI MC96.1) differs from IEC 60584-3 color coding, which differs from British, French, Japanese, and other color standards. Still further, thermocouples with more wires are even more complex and subject to mis-wiring.

If a thermocouple is wired incorrectly, such mis-wiring can lead to unwanted process start-up costs, safety issues, service trips, faulty temperature determinations, and the like.

### SUMMARY

In one embodiment, a temperature transmitter assembly includes a sensor and measurement circuitry. The sensor includes a first conductor, a second conductor, and a third conductor configured to provide leads for two thermocouples. The first conductor and the third conductor are leads for the first thermocouple and have a first measurement point at a first location. The second conductor and the third conductor are leads for the second thermocouple and have a second measurement point at a second location a distance from the first location at a surface of a process conduit. The measurement circuitry includes three terminals, a first terminal for the first conductor, a second terminal for the second conductor, and a third terminal for the third conductor. The measurement circuitry is configured to determine an output related to a temperature at each thermocouple measurement point, the output indicative of a wiring state of the three conductors to the three terminals.

In another embodiment, a method of diagnosing mis-wiring of first, second and third conductors for a three conductor sensor, the first conductor and the third conductor for a first thermocouple and the second conductor and the third conductor for a second thermocouple, the three conductors connected to first, second and third terminals of diagnostic circuitry includes measuring with diagnostic circuitry a first resistance between the first and third terminals and a second resistance between the second and third terminals. The method also includes measuring a first temperature at a first measurement point at a first location, and measuring a second temperature at a second measurement point a distance from the first measurement point at a surface of a process conduit, and measuring a reference temperature at the diagnostic circuitry. Identifying mis-wiring of the first, second, and third conductors to the first, second, and third terminals is accomplished using at least one of the measured resistances and the measured temperatures.

This summary is not intended to describe each disclosed embodiment or every implementation of sensor mis-wiring diagnostics as described herein. Many other novel advantages, features, and relationships will become apparent as this description proceeds. The figures and the description that follow more particularly exemplify illustrative embodiments.

### BRIEF DESCRIPTION OF THE DRAWINGS

FIG. 1A is a block diagram of a temperature transmitter assembly according to an embodiment of the present disclosure;

FIG. 1B is a block diagram of a representative terminal connection according to an embodiment of the present disclosure;

FIG. 1C is a block diagram of a three-wire dual-thermocouple sensor according to an embodiment of the present disclosure;

FIG. 2 is a block diagram of a terminal and thermocouple connection according to an embodiment of the present disclosure;

FIG. 3 is a partial block diagram of an analog to digital converter chip amenable for use with embodiments of the present disclosure; and

FIG. 4 is a flow chart diagram of a method according to an embodiment of the present disclosure.

### DETAILED DESCRIPTION OF ILLUSTRATIVE EMBODIMENTS

In general, embodiments of the present disclosure are directed toward a transmitter and transmitter diagnostics to detect customer mis-wiring of a three lead, two thermocouple sensor such as a three conductor (3 wire) sensor comprising two thermocouples, in which each thermocouple has a positive lead and shares a single negative lead with the other thermocouple, and in which all three conductors are connected to appropriate diagnostic circuitry.

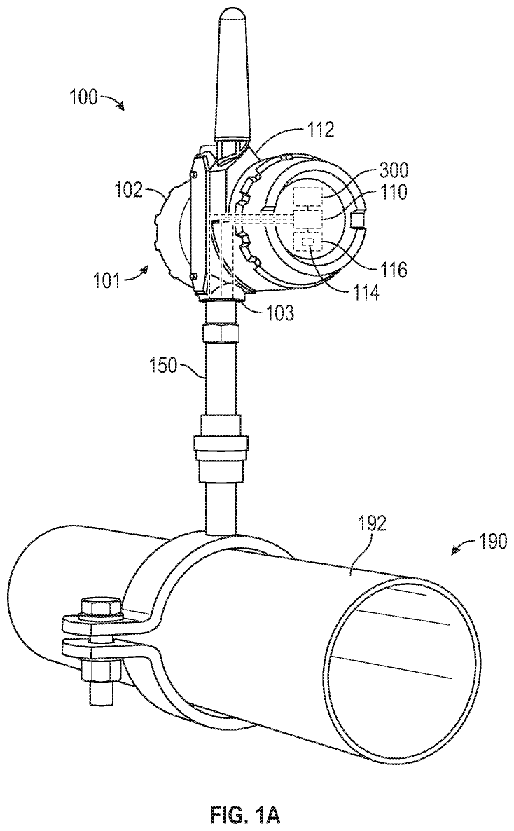

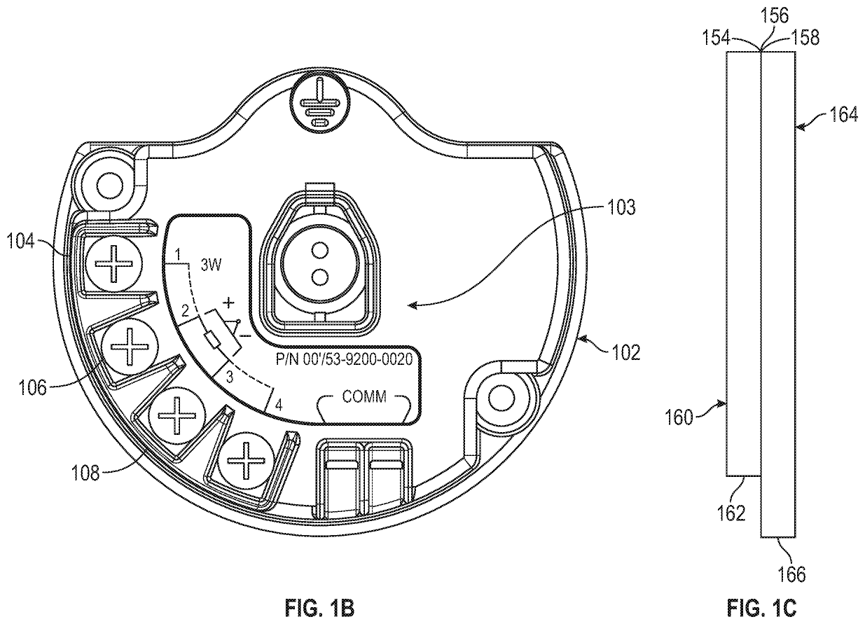

A representative temperature transmitter assembly 100 is shown in FIG. 1. Temperature transmitter assembly 100 includes transmitter 101 and sensor 150. Transmitter 101 includes body 102 having three terminal connections 104, 106, and 108. The terminals 104, 106, 108 are coupled to diagnostic circuitry 110, which includes in one embodiment electrical circuitry for measuring resistance between terminals, a processor or the like configured to accept resistance measurements from the circuitry, and to determine measured temperatures at the thermocouple measurement points, and the like. Transmitter 101 in one embodiment has communication circuitry 112 for communication via a wired or wireless connection. Transmitter 101 also has in one embodiment a reference temperature 114 measured by a measurement component 116 at the diagnostic circuitry. This is used as a reference temperature for thermocouple temperature measurements.

Sensor 150, such as an X-well Extended Range Sensor from Rosemount, Inc., has, in one embodiment, three conductors (e.g., leads) 154, 156, and 158. In order to provide proper transmitter temperature measurements, the three leads are coupled to three terminals of the transmitter diagnostics. Such terminals may be coupled to circuitry and/or a processor or other computer capable of measuring and interpreting signals from the thermocouples, including but not limited to resistance measurements and temperature determinations for measurement points of the thermocouples. A sensor like the X-Well Extended Range Sensor does not have a thermowell or process penetration. Instead, measurements are made at the transmitter sensor (ambient/reference), the pipe surface, and a location separate from the pipe surface. This solution calculates process temperature via a thermal conductivity algorithm. This calculation takes into account the thermal conductive properties of the assembly and pipe for reliable and accurate process temperature measurements.

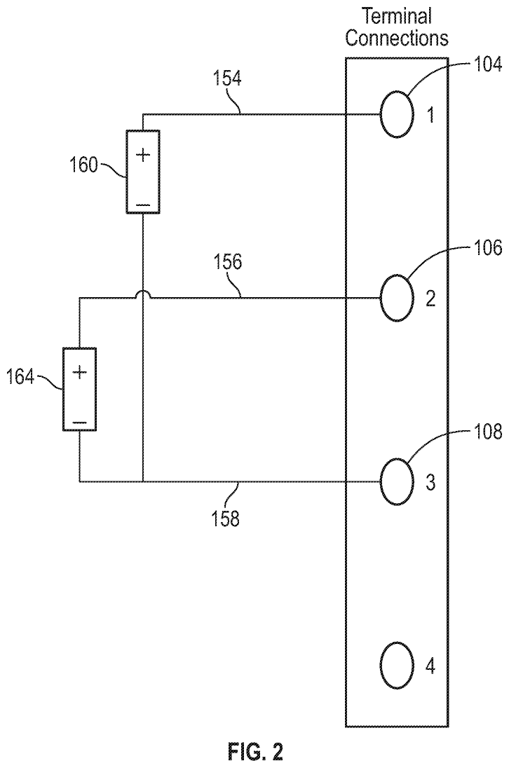

The conductors 154, 156, and 158 of sensor 150 are configured to provide leads for two thermocouples 160 and 164, as shown in FIG. 2. Conductors 154 and 156 are positive leads for the first and second thermocouples 160 and 164, respectively. Conductor 158 is a common negative lead for the two thermocouples. The first conductor 154 and the third conductor 158 are positive and negative leads for the first thermocouple 160. First thermocouple 160 may be referred to as a secondary thermocouple or secondary sensor. First thermocouple has a first measurement point 162. In one embodiment, the measurement point 162 is placed at a first location, in one embodiment a location away from a surface 192 of a process conduit pipe 190. The second conductor 154 and the third conductor 156 are positive and negative leads for the second thermocouple 164. Second thermocouple 164 may be referred to as a surface thermocouple or surface sensor. Second thermocouple 164 has a second measurement point 166 located in one embodiment at a second location, in one embodiment at the surface 192 of the process conduit pipe 190, a distance from the first location.

It should be noted that the same reference numerals are used in different figures for same or similar elements. It should also be understood that the terminology used herein is for the purpose of describing embodiments, and the terminology is not intended to be limiting. Unless indicated otherwise, ordinal numbers (e.g., first, second, third, etc.) are used to distinguish or identify different elements or steps in a group of elements or steps, and do not supply a serial or numerical limitation on the elements or steps of the embodiments thereof. For example, “first,” “second,” and “third” elements or steps need not necessarily appear in that order, and the embodiments thereof need not necessarily be limited to three elements or steps. It should also be understood that, unless indicated otherwise, any labels such as “left,” “right,” “front,” “back,” “top,” “bottom,” “forward,” “reverse,” “clockwise,” “counter clockwise,” “up,” “down,” or other similar terms such as “upper,” “lower,” “aft,” “fore,” “vertical,” “horizontal,” “proximal,” “distal,” “intermediate” and the like are used for convenience and are not intended to imply, for example, any particular fixed location, orientation, or direction. Instead, such labels are used to reflect, for example, relative location, orientation, or directions. It should also be understood that the singular forms of “a,” “an,” and “the” include plural references unless the context clearly dictates otherwise.

In the examples provided herein, it is assumed that the heat flow through the wall of the pipe 190 matches the heat flow between the first (secondary location) thermocouple 160 and the second (surface) thermocouple 164 to simplify the math needed to create the following table. However, it should be understood that when parameters of heat flow are known or measureable, the locations may be different, with different calculations, taking into account known without departing from the scope of the disclosure.

With three conductors 154, 156, and 158, and three terminals 104, 106, and 108, there are six different ways to connect the conductors to the terminals. Only one way is correct. Miswirings can be determined in one embodiment by comparing the resistance of the surface thermocouple 164 to the resistance of the secondary thermocouple 160. This is possible because typical positive leads (e.g., those made of Nicrosil) have almost three times the electrical resistance of the typical negative lead (e.g., those made of Nisil). When miswired, the sensor can report incorrect on-scale measurements, and it may be difficult for a user to determine between mis-wiring, misconfiguration of the sensor feature, sensor installation issues, a faulty sensor, or the like. Such mis-wiring may occur at the transmitter's terminal block, or in any extension wiring connections. It should be understood that different configurations of the terminals and conductors may be used without departing from the scope of the disclosure. In such configurations, the tables for mis-wiring would reflect those changed configurations, but the principles and interpretations remain the same.

Diagnostic (or measurement) circuitry 110 in one embodiment includes the terminals 104, 106, and 108, but they may be separate and electrically coupled to diagnostic circuitry 110. In a correct wiring configuration, the proper conductors of the sensor 150 are connected to the terminals 104, 106, and 108, a first terminal 104 for the first conductor 154, a second terminal 106 for the second conductor 156, and a third terminal 108 for the third conductor 158. The measurement circuitry 110 is configured in one embodiment to determine an output related to a temperature at each thermocouple measurement point, the output indicative of a wiring state of the three conductors to the three terminals.

The six ways of connection of three leads, secondary positive (2+) of thermocouple 1 (TC1), surface positive (S+) of thermocouple 2 (TC2), and common negative (−), are illustrated in Table 1.

TABLE 1

| | | Terminal | Terminal | Terminal |
|---|---|---|---|---|
| | | 1 (104) - | 2 (106) - | 3 (108) - |
| Scenario | Wiring | TC1 (2+) | TC2 (S+) | common (−) |
| 1 | Correct | 2+ | S+ | − |
| 2 | S+/− swap | 2+ | − | S+ |
| 3 | 2+/− swap | − | S+ | 2+ |
| 4 | S+/2+ swap | S+ | 2+ | − |
| 5 | All wrong 1 | − | 2+ | S+ |
| 6 | All wrong 2 | S+ | − | 2+ |

Based on how thermocouples work (Seebeck effect and cold junction correction (CJC)), Table 2 illustrates one example of what a user might see for each temperature measurement based on the 6 possible wiring scenarios of a three wire dual thermocouple sensor as described herein:

TABLE 2

| | Correct | S+/− | 2+/− | S+/2+ | All wrong | All wrong |
|---|---|---|---|---|---|---|
| | Wiring | swap | swap | swap | 1 | 2 |
| Scenario → | 1 | 2 | 3 | 4 | 5 | 6 |
| Terminal/Reference Temp. | 20° | 20° | 20° | 20° | 20° | 20° |
| Secondary Temperature | 85° | 20° | −45° | 100° | −60° | 20° |
| (TC1) | | | | | | |
| Surface Temperature | 100° | −60° | 20° | 85° | 20° | −45° |
| (TC2) | | | | | | |
| Calculated Process | 115° | −65°, low | 95° | 70° | 100° | −65°, low |
| Temperature Output | | limited | | | | limited |

Note that this is just one example, but it illustrates how difficult it can be for a user to look at the resulting process temperature calculated output and know if the sensor is wired correctly.

In one embodiment, the temperature transmitter assembly 100 uses resistance measurements for each thermocouple to determine the wiring configuration of the three conductors to the three terminals.

In scenario 1, a correctly wired scenario, the measurement circuitry 110 compares measured resistance for each thermocouple by measuring resistance at the connected terminals 104, 106, and 108, and identifies a correct wiring of the three conductors 154, 156, and 158 to the three terminals 104, 106, and 108 respectively, when there is substantially no resistance difference (negligible resistance difference, or in a ratio of less than 1:1) between resistances of the two thermocouples 160 and 164. In the other scenarios, the five incorrect wiring scenarios are shown. The measurement circuitry determines an incorrect wiring of at least two of the first conductor 154, second conductor 156, and third conductor 158 by determining a resistance difference of a resistance between the first and third terminals 104 and 108 and a resistance between the second and third terminals 106 and 108. This corresponds to measuring resistance of the first thermocouple 160 and the second thermocouple 164, respectively.

In scenario 4, the positive leads are swapped. In this scenario, the measurement circuitry 110 identifies connection of the first conductor 154 to the second terminal 106, the second conductor 156 to the first terminal 104, and the third conductor 158 to the third terminal 108 when resistance between the first terminal 104 and the third terminal 108 is different than resistance between the second terminal 106 and the third terminal 108 in a ratio slightly greater than 1:1, provided it is measurably different Alternatively, in this scenario, the resistance between the first terminal and the second terminal would be significantly greater than the resistance between the second terminal and the third terminal in a ratio of significantly greater than 1:1.

In scenario 2, the positive and negative leads of the second (surface) thermocouple 164 are swapped. In scenario 6, all the leads are wrongly connected, with the second lead 156 connected to the first terminal 104, the third lead 158 connected to the second terminal 106, and the first lead 154 connected to the third terminal 108. In these scenarios, the measurement circuitry 110 identifies the mis-wirings when resistance between the first terminal 104 and the third terminal 108 is greater than resistance between the second terminal 106 and the third terminal 108 in a ratio of significantly greater than 1:1 for a typical thermocouple as described herein. For example, with a thermocouple having positive leads of about three times the resistance of negative leads, the ratio would be on the order of 3:2. It should be understood that the ratio may vary based on lead length and lead material.

In scenario 3, the positive and negative leads of the first (secondary) thermocouple 160 are swapped. In scenario 5, all the leads are wrongly connected, with the third lead 158 connected to the first terminal 104, the first lead 154 connected to the second terminal 106, and the second lead 156 connected to the third terminal 108. In these scenarios, the measurement circuitry identifies the mis-wirings when resistance between the second terminal and the third terminal is greater than resistance between the first terminal and the third terminal in a ratio of significantly greater than 1:1.

In another embodiment, the temperature transmitter assembly 100 uses measured temperatures for each thermocouple and the reference temperature 114 measured by component 116 at the measurement circuitry 110 to determine the wiring configuration of the three conductors to the three terminals.

In scenario 1, a correctly wired scenario, the measurement circuitry 110 compares measured temperature for each thermocouple 160, 164 and the reference temperature 114 and identifies a correct wiring of the three conductors 154, 156, and 158 to the three terminals 104, 106, and 108 respectively, of the sensor 150 when the temperature at the second measurement point 166 is greater than the temperature at the first measurement point 162, which is greater than the reference temperature 114 at measurement circuitry 110 for a hot process; or when the temperature at the second measurement point 166 is lower than the temperature at the first measurement point 162, which is lower than the reference temperature 114 at measurement circuitry 110 for a cold process.

In scenario 4, the positive leads are swapped. In this scenario, the measurement circuitry 110 identifies connection of the first conductor 154 to the second terminal 106, the second conductor 156 to the first terminal 104, and the third conductor 158 to the third terminal 108 when the measured temperature at the first measurement point 162, the measured temperature at the second measurement point 166, and the reference temperature 114 at the measurement circuitry 110 are not consistent. A not consistent set of temperature measurements comprises in one embodiment a set of temperature readings that are not like those of a correct scenario. For example, as shown above in Table 2, in a correct wiring scenario, provided there is a sufficient difference in temperature between the process and the terminal, a correctly wired three-conductor dual-thermocouple sensor will have a temperature at the transmitter (reference temperature) lower than the secondary temperature which is lower than the surface temperature if the process is a hot process. The sensor will have a temperature at the transmitter (reference temperature) higher than the secondary temperature which is higher than the surface temperature for a cold process. As shown in the exemplary surface/secondary positive lead swap of Table 2, that pattern does not hold. Such an inconsistent pattern with the close resistance measurements of the two thermocouples indicates the incorrect wiring of scenario 4.

In scenario 2, the positive and negative leads of the second (surface) thermocouple 164 are swapped. In scenario 6, all the leads are wrongly connected, with the second lead 156 connected to the first terminal 104, the third lead 158 connected to the second terminal 106, and the first lead 154 connected to the third terminal 108. In these scenarios, the measurement circuitry 110 identifies the mis-wirings when the measured temperature at the first measurement point 162 and the reference temperature 114 measured at the measurement circuitry 110 are substantially the same.

In scenario 3, the positive and negative leads of the first (secondary) thermocouple 160 are swapped. In scenario 5, all the leads are wrongly connected, with the third lead 158 connected to the first terminal 104, the first lead 154 connected to the second terminal 106, and the second lead 156 connected to the third terminal 108. In these scenarios, the measurement circuitry identifies the mis-wirings when the measured temperature at the second measurement point 166 and the reference temperature 114 are substantially the same.

In yet another embodiment, the temperature transmitter assembly 100 measures, with measurement circuitry 110, resistance for each thermocouple via the three terminals 104, 106, and 108, temperature for the measurement point 162, 166 of each thermocouple 160, 164, respectively, via the three terminals 104, 106, and 108, and a reference temperature 114 at the measurement circuitry 110 via temperature component 116. Combinations of the resistances and temperatures are used to identify mis-wiring scenarios as described above for each of resistance and temperature. Specifically, the temperature transmitter assembly 100 identifies mis-wiring of the first, second, and third conductors 154, 156, and 158 to the first, second, and third terminals 104, 106, and 108 using at least one of the combination of measured resistances and measured temperatures.

In one embodiment, the measurement circuitry determines correct wiring when at least one of measured resistance difference between resistances of the two thermocouples is equal, and measured temperature at the second measurement point 166 is greater than measured temperature at the first measurement point 162 which is greater than the reference temperature 114 for a hot process; or measured temperature at the second measurement point 166 is lower than measured temperature at the first measurement point 162 which is lower than the reference temperature 114 for a cold process.

The measurement circuitry determines a swap of the positive leads of the two thermocouples has occurred when at least one of measured resistance between the first terminal and the third terminal is different than resistance between the second terminal and the third terminal in a ratio greater than and about 1:1; and measured temperature at the first measurement point, the measured temperature at the second measurement point, and the reference temperature are not consistent. A not consistent set of temperature measurements is described above.

The measurement circuitry determines second thermocouple lead swap (scenario 2) or third conductor at first terminal, first conductor at third terminal, and third conductor at second terminal (scenario 6), when at least one of measured resistance between the first terminal and the third terminal is greater than measured resistance between the second terminal and the third terminal in a ratio of significantly greater than 1:1; and measured temperature at the first measurement point and the reference temperature are substantially the same.

The measurement circuitry determines first thermocouple lead swap (scenario 3) or third conductor at first terminal, first conductor at second terminal, and second conductor at third terminal (scenario 5), when at least one of measured resistance between the second terminal and the first terminal is greater than measured resistance between the first terminal and the third terminal in a ratio of significantly greater than 1:1; and measured temperature at the second measurement point and the reference temperature are substantially the same.

Once a mis-wiring of conductors to terminals is identified, the mis-wiring will be one of three types, identified by either or both of the resistance measurements and the temperature measurements of the diagnostic circuitry 110. The first mis-wiring type, mis-wiring as in scenario 4 of Table 1, is a swap of the positive conductors of the two thermocouples. The second mis-wiring type, mis-wiring as in scenarios 2 and 6 of Table 1, has two positive conductors on the first thermocouple. In the second mis-wiring type, there is at least one of a resistance difference in which the first thermocouple resistance is greater than the second thermocouple resistance and the reference temperature 114 and the temperature at the first measurement point 162 (of thermocouple 160) are substantially equal. The third mis-wiring type, mis-wiring as in scenarios 3 and 5 of Table 1, has two positive conductors on the second thermocouple. In the third mis-wiring type, there is at least one of a resistance difference in which the second thermocouple resistance is greater than the first thermocouple resistance and the reference temperature 114 and the temperature at the second measurement point 166 (of thermocouple 164) are substantially equal. In each of these scenarios, logic may be used with the measurement circuitry to correct the mis-wirings once they are identified.

For example, once software/firmware/hardware of the temperature transmitter assembly 100 identifies, as described above, that a mis-wiring has occurred, the diagnostic circuitry 110, or another component may be adjusted to compensate for inaccurate wiring without actually rewiring the assembly 100.

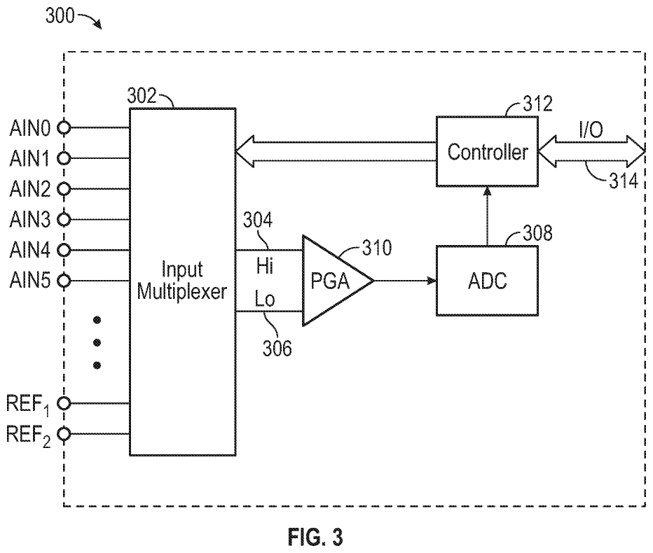

Correction of scenarios with software/firmware/hardware may be accomplished in one embodiment using a multiplexer or multiplexers. Referring to FIG. 3, a typical analog to digital converter chip (ADC chip) 300 is shown. This type of ADC chip has a multiplexed input feeding a multiplexer 302. The input is very flexible as to what inputs can be connected to what outputs. For example, the ADC chip 300 of FIG. 3 is capable of connecting any of six inputs AlN0, AlN1, AlN2, AlN3, AlN4, and AlN5 to either the high 304 or low 306 input of a sigma-delta converter 308 shown therein through programmable gain amplifier (PGA) 310. Controller 312 is coupled to control the input multiplexer 302 and provide input/output functions though I/O circuitry 314. In use with the three wire sensor embodiments described herein, a sigma-delta converter is a measurement topology used in process transmitters and allows for measurements of a differential signal. It should be understood that while the ADC chip 300 shown is amenable to use with embodiments of the present disclosure, other analog to digital sensing topologies that also have multiplexed inputs exist and may be used with embodiments of the present disclosure without departing therefrom. The image of FIG. 3 is only an example input scheme. Many available chips on the market today may also be employed. In one embodiment, each sensor conductor 154, 156, 158, would be connected to one of the AlNx lines, which can be routed to either the high 304 or low 306 multiplexer outputs as shown.

One solution for correcting a sensor mis-wiring as described above is for the transmitter diagnostic circuitry 110 to adjust which AlNx input goes to the high 304 and low 306 multiplexer outputs. In traditional systems, a predefined input is typically hardwired to either the high or low input.

In one embodiment, new logic is provided for the diagnostic circuitry to properly route the inputs to the high 304 and low 306 outputs of the multiplexer 302 according to known mis-wiring. For example, when the wiring is determined to be correct, traditional input to output configuration may be used, with terminal 104 routed to AlN0, terminal 106 routed to AlN1, and terminal 108 routed to AlN2. When positive leads are swapped as in scenario 4, then the logic routes terminal 104 to AlN1 and terminal 106 to AlN0 instead. Similar logic swaps will be evident for all five mis-wiring scenarios. In a situation in which it is to be determined which mis-wiring type is present for scenarios 2 and 6, a process may be used to first swap terminals 106 and 108 and recheck. If the wiring appears correct after that swap, then that configuration is used as a scenario 2 mis-wiring. If the readings from the first swap now show scenario 4, the mis-wiring was scenario 6, and terminals 104 and 106 are swapped. Similarly, with miswring of type 3 or 5, terminals 104 and 108 are swapped, and if the wiring then appears correct, the mis-wiring is scenario 3. If the readings after the swap indicate scenario 4, then terminals 104 and 106 are swapped and the mis-wiring was a scenario 5 mis-wiring. New logic may be used for the five different mis-wiring combinations described above in Table 1. No updates are necessary for measurement transfer functions or manufacturing processes.

In another embodiment, the sensor input multiplexer high/low logic remains the same, but the miswired measurements are inverted after the sigma-delta scan completes. The ADC chip 300 is capable of reading an equal magnitude in the positive and negative polarities (e.g., +/−76 mV). Using the embodiments described herein, the miswired scans will be of known type, and can be inverted prior to processing the data through the standard transfer function.

The mis-wiring corrections described herein allow for automatic correction of a 3-wire dual-thermocouple sensor mis-wiring through dynamic A/D input multiplexing. Alternatively, the mis-wiring corrections described herein may also be achieved by inverting a measurement prior to processing the value in the sensor transfer function.

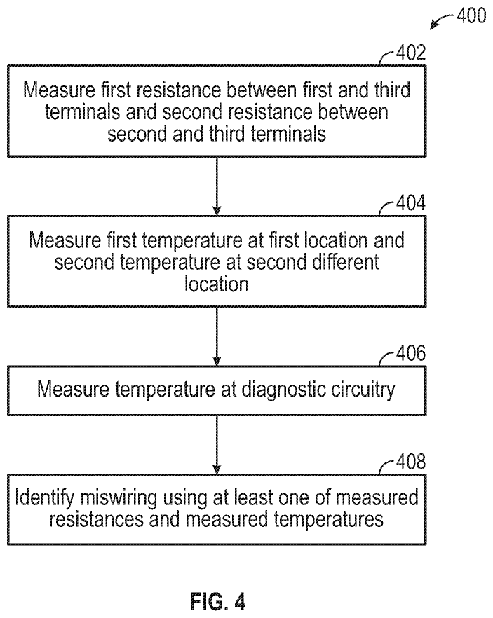

A method 400 of diagnosing mis-wiring of first, second and third conductors for a three conductor sensor, the first conductor and the third conductor for a first thermocouple and the second conductor and the third conductor for a second thermocouple, the three conductors connected to first, second and third terminals of diagnostic circuitry, is shown in flow chart form in FIG. 4. Method 400 comprises, in one embodiment, measuring with diagnostic circuitry a first resistance between the first and third terminals and a second resistance between the second and third terminals in block 402. Further, in block 404, the method comprises measuring a first temperature at a first measurement point at a first location, and measuring a second temperature at a second measurement point a distance from the first measurement point at a surface of a process conduit. A reference temperature is measured at the diagnostic circuitry in block 406. Miswiring of the first, second, and third conductors to the first, second, and third terminals is identified using at least one of the measured resistances and the measured temperatures in block 408.

It should be understood that identifying mis-wiring may be done with either resistance measurements, temperature measurements, or a combination of the two. Therefore a method of identifying mis-wiring may only determine temperatures, or may only determine resistances, and still be able to identify mis-wiring. A combination allows use of the most efficient or accurate of either measurements, or a combination of the two, without departing from the scope of the disclosure.

Embodiments of the present disclosure therefore provide a diagnostic for determining mis-wiring of the three conductors of a three-conductor, dual-thermocouple sensor, and for correcting the mis-wiring without changing a physical configuration of the wiring itself.

The above-disclosed subject matter is to be considered illustrative, and not restrictive, and the appended claims are intended to cover all such modifications, enhancements, and other embodiments, which fall within the true scope of the present disclosure. Thus, to the maximum extent allowed by law, the scope of the present disclosure is to be determined by the broadest permissible interpretation of the following claims and their equivalents, and shall not be restricted or limited by the foregoing detailed description.

What is claimed is:

1. A temperature transmitter assembly, comprising:
a sensor comprising a first conductor, a second conductor, and a third conductor configured to provide leads for two thermocouples, the first conductor and the third conductor being leads for the first thermocouple and having a first measurement point at a first location, and the second conductor and the third conductor being leads for the second thermocouple and having a second measurement point at a second location a distance from the first location and at a surface of a process conduit; and
measurement circuitry comprising three terminals, a first terminal for the first conductor, a second terminal for the second conductor, and a third terminal for the third conductor, the measurement circuitry configured to determine an output related to a temperature at each thermocouple measurement point, the output indicative of a wiring state of the three conductors to the three terminals.

2. The temperature transmitter assembly of claim 1, wherein the measurement circuitry measures resistance for each thermocouple via the three terminals.

3. The temperature transmitter assembly of claim 2, wherein the measurement circuitry compares measured resistance for each thermocouple by measuring resistance at the connected terminals, and identifies a correct wiring of the three conductors when there is a negligible resistance difference between resistances of the two thermocouples.

4. The temperature transmitter assembly of claim 2, wherein the measurement circuitry determines an incorrect wiring of the first conductor, second conductor, and third conductor by determining a resistance difference of a resistance between the first and third terminals and a resistance between the second and third terminals.

5. The temperature transmitter assembly of claim 4, wherein the measurement circuitry identifies a swap of the first conductor and the second conductor when resistance between the first terminal and the third terminal is different than resistance between the second terminal and the third terminal in a ratio slightly greater than 1:1.

6. The temperature transmitter assembly of claim 4, wherein the measurement circuitry identifies a swap of the second and third conductors; or connection of the second conductor to the first terminal, the third conductor to the second terminal, and the first conductor to the third terminal, respectively, when resistance between the first terminal and the third terminal is greater than resistance between the second terminal and the third terminal in a ratio of significantly greater than 1:1.

7. The temperature transmitter assembly of claim 4, wherein the measurement circuitry identifies a swap of the first and third conductors, or connection of the third conductor to the first terminal, the first conductor to the second terminal, and the second conductor to the third terminal, respectively, when resistance between the second terminal and the third terminal is greater than resistance between the first terminal and the third terminal in a ratio of significantly greater than 1:1.

8. The temperature transmitter assembly of claim 1, wherein the measurement circuitry measures temperature for the measurement point of each thermocouple via the three terminals, and a reference temperature at the measurement circuitry.

9. The temperature transmitter assembly of claim 8, wherein the measurement circuitry compares measured temperature for each thermocouple and the reference temperature and identifies a correct wiring of the three conductors when the temperature at the second measurement point is greater than the temperature at the first measurement point which is greater than the reference temperature for a hot process; or when the temperature at the second measurement point is lower than the temperature at the first measurement point which is lower than the reference temperature for a cold process.

10. The temperature transmitter assembly of claim 9, wherein the measurement circuitry identifies swapping of the first and second conductors when the measured temperature at the first measurement point, the measured temperature at the second measurement point, and the reference temperature are not consistent.

11. The temperature transmitter assembly of claim 8, wherein the measurement circuitry identifies a swap of the second and third conductors; or connection of the second conductor to the first terminal, the third conductor to the second terminal, and the first conductor to the third terminal, respectively, when the measured temperature at the first measurement point and the reference temperature are substantially the same.

12. The temperature transmitter assembly of claim 8, wherein the measurement circuitry identifies a swap of the first and third conductors; or connection of the third conductor to the first terminal, the first conductor to the second terminal, and the second conductor to the third terminal, respectively, when the measured temperature at the second measurement point and the reference temperature are substantially the same.

13. The temperature transmitter assembly of claim 1, wherein the measurement circuitry measures:
resistance for each thermocouple via the three terminals; and
temperature for the measurement point of each thermocouple via the three terminals, and a reference temperature at the measurement circuitry.

14. The temperature transmitter assembly of claim 13, wherein the measurement circuitry identifies mis-wiring of the first, second, and third conductors to the first, second, and third terminals using at least one of the measured resistances and the measured temperatures.

15. The temperature transmitter assembly of claim 14, wherein the measurement circuitry:
determines correct wiring when at least one of:
measured resistance difference between resistances of the two thermocouples is equal; and
measured temperature at the second measurement point is greater than measured temperature at the first measurement point which is greater than the reference temperature for a hot process; or measured temperature at the second measurement point is lower than measured temperature at the first measurement point which is lower than the reference temperature for a cold process;
determines swap of first conductor and the second conductor when at least one of:
measured resistance between the first terminal and the third terminal is different than resistance between the second terminal and the third terminal in a ratio slightly greater than 1:1; and
measured temperature at the first measurement point, the measured temperature at the second measurement point, and the reference temperature are not consistent;
determines a swap of the second conductor and the third conductor, or connection of the second conductor to the first terminal, the third conductor to the second terminal, and the first conductor to the third terminal, respectively, when at least one of:
measured resistance between the first terminal and the third terminal is greater than resistance between the second terminal and the third terminal in a ratio of significantly greater than 1:1; and
measured temperature at the first measurement point and the reference temperature are substantially the same;
determines a swap of the first conductor and the third conductor, or connection of the third conductor to the first terminal, the first conductor to the second terminal, and the second conductor to the third terminal, respectively, when at least one of:
measured resistance between the second terminal and the third terminal is greater than measured resistance between the first terminal and the third terminal in a ratio of significantly greater than 1:1; and
measured temperature at the second measurement point and the reference temperature are substantially the same.

16. The temperature transmitter assembly of claim 1, wherein the measurement circuitry is configured to correct mis-wiring without rewiring by routing signals from terminals to a corrective circuit.

17. The temperature transmitter assembly of claim 16, wherein the measurement circuitry is configured to correct mis-wiring by routing signals from terminals to the corrective circuit either before analog to digital conversion or after analog to digital conversion.

18. A method of diagnosing mis-wiring of first, second and third conductors for a three conductor sensor, the first conductor and the third conductor for a first thermocouple and the second conductor and the third conductor for a second thermocouple, the three conductors connected to first, second and third terminals of diagnostic circuitry, the method comprising:
measuring with diagnostic circuitry a first resistance between the first and third terminals and a second resistance between the second and third terminals;
measuring a first temperature at a first measurement point at a first location, and measuring a second temperature at a second measurement point a distance from the first measurement point at a surface of a process conduit;
measuring a reference temperature at the diagnostic circuitry; and
identifying mis-wiring of the first, second, and third conductors to the first, second, and third terminals using at least one of the measured resistances and the measured temperatures.

19. The method of claim 18, wherein the diagnostic circuitry determines correct wiring in the event of at least one of:
measured resistance difference between resistances of the two thermocouples is equal; and
measured temperature at the second measurement point is greater than measured temperature at the first measurement point which is greater than the reference temperature for a hot process; or when measured temperature at the second measurement point is lower than measured temperature at the first measurement point which is lower than the reference temperature for a cold process.

20. The method of claim 18, wherein the diagnostic circuitry determines a swap of the second and the third conductor, or connection of the second conductor to the first terminal, the third conductor to the second terminal, and the first conductor to the third terminal, respectively, in the event of at least one of:
measured resistance between the first terminal and the third terminal is greater than resistance between the second terminal and the third terminal in a ratio of significantly greater than 1:1; and
measured temperature at the first measurement point and the reference temperature are substantially the same.

21. The method of claim 18, wherein the diagnostic circuitry determines a swap of the first conductor and the third conductor, or connection of the third conductor to the first terminal, the first conductor to the second terminal, and the second conductor to the third terminal, respectively, in the event of at least one of:
measured resistance between the second terminal and the third terminal is greater than measured resistance between the first terminal and the third terminal in a ratio of significantly greater than 1:1; and
measured temperature at the second measurement point and the reference temperature are substantially the same.

22. The method of claim 18, wherein the diagnostic circuitry determines a swap of the first conductor and the second conductor in the event of at least one of:
measured resistance between the first terminal and the third terminal is different than resistance between the second terminal and the third terminal in a ratio greater than and about 1:1; and
measured temperature at the first measurement point, the measured temperature at the second measurement point, and the reference temperature are not consistent.

23. The method of claim 16, and further comprising correcting mis-wiring without rewiring by routing signals from terminals by a corrective circuit.

24. The method of claim 17, wherein correcting mis-wiring is accomplished by routing signals either before analog to digital conversion or after analog to digital conversion.
